(19) United States
(12) Patent Application Publication
(10) Pub. No.: US 2026/0175935 A1
(43) Pub. Date: Jun. 25, 2026

(54) ELECTRICAL COMPONENT INSTALLATION STRUCTURE

(71) Applicant: SUZUKI MOTOR CORPORATION, Hamamatsu-shi (JP)

(72) Inventor: Yoshiaki MATSUURA, Hamamatsu-shi (JP)

(73) Assignee: SUZUKI MOTOR CORPORATION, Hamamatsu-shi (JP)

(21) Appl. No.: 19/332,385

(22) Filed: Sep. 18, 2025

(30) Foreign Application Priority Data
Dec. 20, 2024 (JP) 2024-225338

(51) Int. Cl. B62J 45/00; B62J 40/00; B62K 11/00; F16F 15/08; H05K 5/02

(52) U.S. Cl. CPC B62J 45/00; B62J 40/00; B62K 11/00; F16F 15/08; H05K 5/0217; F16F 2224/0225; F16F 2224/025; F16F 2230/007

(57) ABSTRACT

An electrical component installation structure includes an air cleaner connected to an engine of a saddle-type vehicle, an electrical component supported from below by the air cleaner, a cover member covering an upper part of the electrical component with a gap, a first cushion sandwiched between the cover member and the electrical component, and a second cushion sandwiched between the air cleaner and the electrical component. The cover member includes a restricting portion configured to restrict a displacement of the electrical component when a vibration larger than an engine vibration occurs.

### CROSS-REFERENCE TO RELATED APPLICATIONS

This application is based on and claims priority under 35 USC 119 from Japanese Patent Application No. 2024-225338 filed on Dec. 20, 2024, the contents of which are incorporated herein by reference.

### BACKGROUND

The present invention relates to an electrical component installation structure.

A saddle-type vehicle is provided with an Engine Control Module (ECM) that controls the vehicle as an electrical component. In a recent year, an ECM installation structure has been known in which an ECM is installed on an upper surface of an air cleaner below a seat (see, for example, Japanese Patent No. 7263534). In the air cleaner described in Japanese U.S. Pat. No. 7,263,534, a dirty side of a cleaner case faces rearward and a clean side of the cleaner case faces forward. An upper surface of the clean side of the cleaner case is recessed to form a recess, and an ECM is placed on a flat bottom surface of this recess to reduce interference between the ECM and a seat.

### SUMMARY

According to one advantageous aspect of the present invention, there is provided an electrical component installation structure, including
an air cleaner connected to an engine of a saddle-type vehicle;
an electrical component supported from below by the air cleaner;
a cover member covering an upper part of the electrical component with a gap;
a first cushion sandwiched between the cover member and the electrical component; and
a second cushion sandwiched between the air cleaner and the electrical component, in which
the cover member includes a restricting portion configured to restrict a displacement of the electrical component when a vibration larger than an engine vibration occurs.

### BRIEF DESCRIPTION OF DRAWINGS

FIG. 1 is a left side view of a saddle-type vehicle according to an embodiment.

FIG. 2 is a top view of a periphery of an air cleaner according to the embodiment.

FIG. 3 is a perspective view of the periphery of the air cleaner according to the embodiment.

FIG. 4 is a perspective view of the air cleaner according to the embodiment.

FIG. 5 is a rear view of a periphery of an ECM according to the embodiment.

FIG. 6 is a top view of the periphery of the ECM according to the embodiment.

### DETAILED DESCRIPTION OF EXEMPLIFIED EMBODIMENTS

It is easy to secure a relatively large flat surface on the upper surface of the air cleaner in order to install an electrical component such as an ECM, but vibration from the engine is transmitted to the surface, making it difficult to satisfy guaranteed vibration resistance value of the electrical component. In addition, saddle-type vehicles are subject to large vibration caused by rough road surface or jump driving. Although effects of large vibration can be reduced by rigidly or tightly fixing an electrical component, there is a drawback in that small vibration from an engine can easily be transmitted to the electrical component.

The present invention is made in consideration of these points, and an object of the present invention is to provide an electrical component installation structure that can suppress effects of not only engine vibration but also vibration larger than engine vibration on an electrical component installed in an air cleaner.

In a saddle-type vehicle according to an aspect of the present invention, an air cleaner is connected to an engine. An electrical component is supported from below by the air cleaner, and is covered by a cover member with a gap at the top. A first cushion is sandwiched between the cover member and the electrical component, a second cushion is sandwiched between the air cleaner and the electrical component, and the electrical component is fixed in a floating manner between the cover member and the air cleaner via the first and second cushions. Engine vibration is absorbed by the first and second cushions, reducing the effect of engine vibration on the electrical component. In addition, the cover member is formed with a restricting portion that restricts displacement of the electrical component when vibration larger than engine vibration occurs, the displacement of the electrical component is restricted by the restricting portion of the cover member, and acceleration of the electrical component is reduced by deformation of the first and second cushions, thereby mitigating an impact applied to the electrical component. In this way, the effects of engine vibration and vibration larger than engine vibration on the electrical component are reduced.

### EMBODIMENT

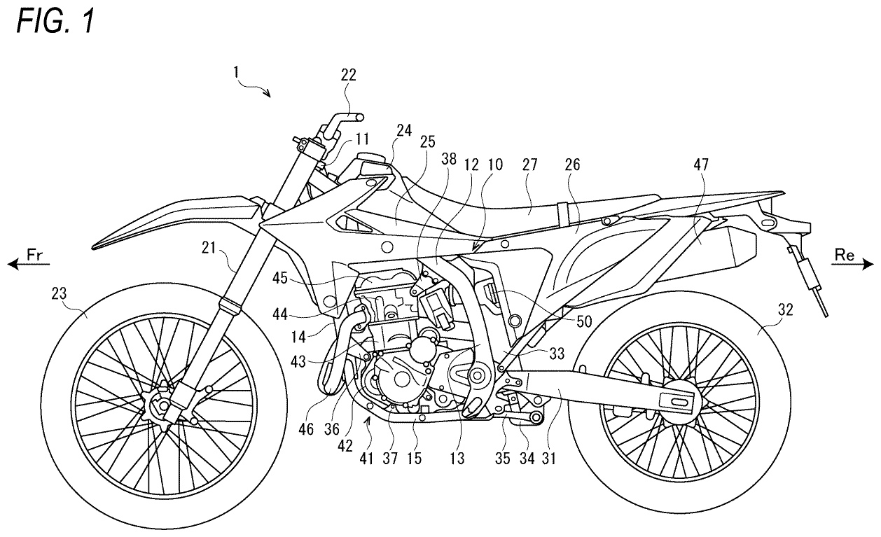

Hereinafter, a saddle-type vehicle according to the present embodiment will be described with reference to the accompanying drawings. FIG. 1 is a left side view of the saddle-type vehicle according to the present embodiment. In the following drawings, an arrow Fr indicates the front of the vehicle, an arrow Re indicates the rear of the vehicle, an arrow L indicates the left side of the vehicle, and an arrow R indicates the right side of the vehicle.

As illustrated in FIG. 1, in a saddle-type vehicle 1 various components such as an engine 41 and an electrical system on a vehicle body frame 10 are mounted. A pair of tank rails 12 extend diagonally downward and rearward from a head pipe 11 of the vehicle body frame 10, splitting into left and right parts. A pair of body frames 13 extend downward from rear portions of the pair of tank rails 12. A down frame 14 extends downward from the head pipe 11, and an underloop 15 bent rearward is connected to a lower part of the down frame 14. A rear end of the underloop 15 is connected to a lower part of the pair of body frames 13, so that the vehicle body frame 10 is formed into a cradle shape.

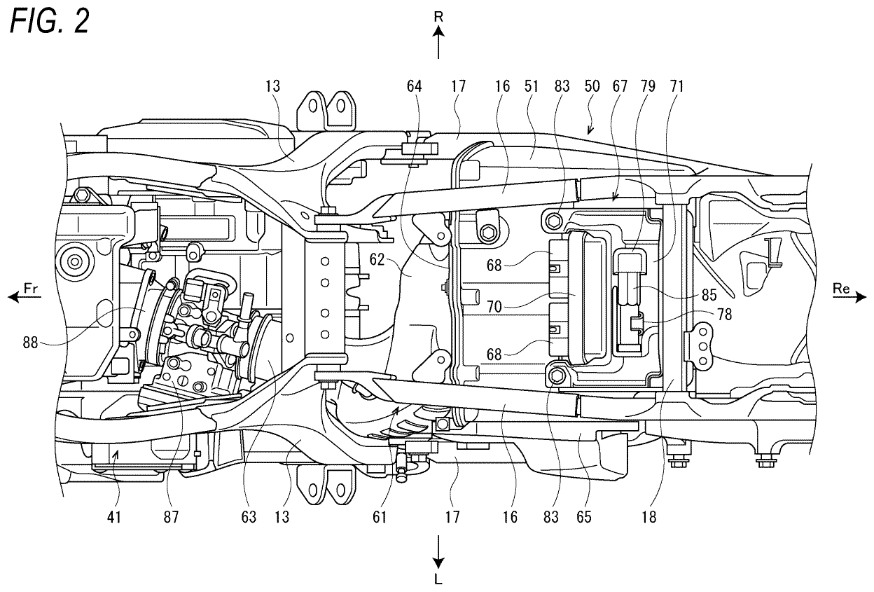

A front fork 21 is supported on the head pipe 11 via a steering shaft (not illustrated) so as to be steerable. A handlebar 22 is provided on an upper part of the front fork 21, and a front wheel 23 is rotatably supported on a lower part of the front fork 21. A fuel tank (not illustrated) is placed on an upper part of the pair of tank rails 12, and the pair of tank rails 12 and the fuel tank are covered by a tank cover 24 and a pair of front side covers 25. A seat 27 is installed behind the tank cover 24, and seat rails 16, 17 (see FIG. 2) that support the seat 27 from below are covered from the sides by a pair of rear side covers 26.

A swing arm 31 is supported by the body frame 13 so as to be able to swing. The swing arm 31 extends rearward from the body frame 13, and a rear wheel 32 is rotatably supported at a rear end of the swing arm 31. A front side of the swing arm 31 and a lower part of a rear suspension 33 are connected via a cushion lever 34. In addition, the cushion lever 34 and the body frame 13 are connected via a cushion rod 35. The rear suspension 33 expands and contracts in accordance with the swing of the swing arm 31, thereby absorbing unevenness in the road surface, suppressing vibration, and improving the contact between the rear wheel 32 and the road surface.

The engine 41 is a single cylinder engine, and is suspended inside the vehicle body frame 10 via suspension brackets 36 to 38. A cylinder assembly, in which a cylinder 43, a cylinder head 44, and a cylinder head cover 45 are stacked, is attached to an upper surface of a crankcase 42 of the engine 41. An exhaust pipe 46 is connected to a front surface of the cylinder head 44. The exhaust pipe 46 passes through a right side of the cylinder 43 and extends rearward, and an up-type muffler 47 that is inclined upward toward the rear is connected to a downstream side of the exhaust pipe 46. Further, an intake device such as an air cleaner 50 is provided behind the cylinder head 44.

Incidentally, an ECM may be installed as an electrical component above the air cleaner. When installing an ECM in a saddle-type vehicle, it is necessary to consider a mounting location and structure that satisfy the ECM's guaranteed vibration resistance value. If the vehicle had few on-board parts, the ECM could be installed in a location with little vibration, using a rubber holder or the like; however, in recent years, compliance with exhaust gas regulations and the addition of new functions have led to larger ECMs and an increase in ancillary equipment, limiting installation space. Although a relatively large flat surface can be secured on the top of the air cleaner, there is a risk that the ECM's guaranteed vibration resistance value will be exceeded due to intake pulsation of the air cleaner or small engine vibration of 50 Hz or more.

Furthermore, rough road surfaces and jump driving frequently cause large vibration of less than 50 Hz. In the specification, the large vibration means a vibration that an amplitude thereof is large. Rigidly fixing the ECM or tightly fixing it using a rubber holder is effective against large vibration, but these types of fixation make it easy for engine vibration of 50 Hz or more to be transmitted to the ECM. Furthermore, when the rubber holder is fixed tightly, the rubber loses flexibility and the vibration absorbing effect is greatly reduced. As described above, in saddle-type vehicles, not only engine vibration of 50 Hz or more but also vibration of less than 50 Hz caused by jump driving, or the like are transmitted to the ECM, and it is necessary to suppress the effects of both types of vibration on the ECM.

Here, the amount of displacement of the ECM caused by vibration of less than 50 Hz due to jump driving or the like is greater than the amount of displacement of the ECM caused by engine vibration of 50 Hz or more. For example, the amount of displacement of the ECM due to engine vibration is approximately 0.4 mm, whereas the amount of displacement of the ECM due to vibration during jump landing is approximately 4.75 mm. Therefore, in the present embodiment, the ECM is fixed in a floating manner to an upper part of the air cleaner via a cushion, thereby suppressing the effect of engine vibration on the ECM. Furthermore, by minimizing the displacement of the ECM fixed in a floating manner, the effects of vibration larger than engine vibration on the ECM are suppressed.

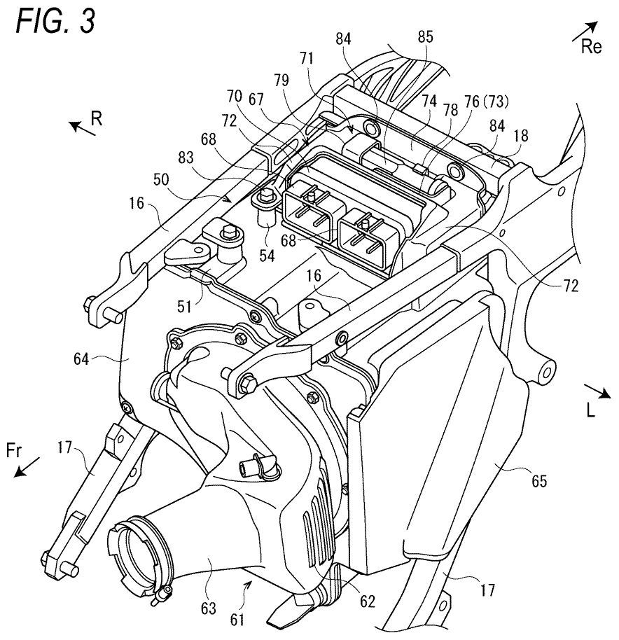

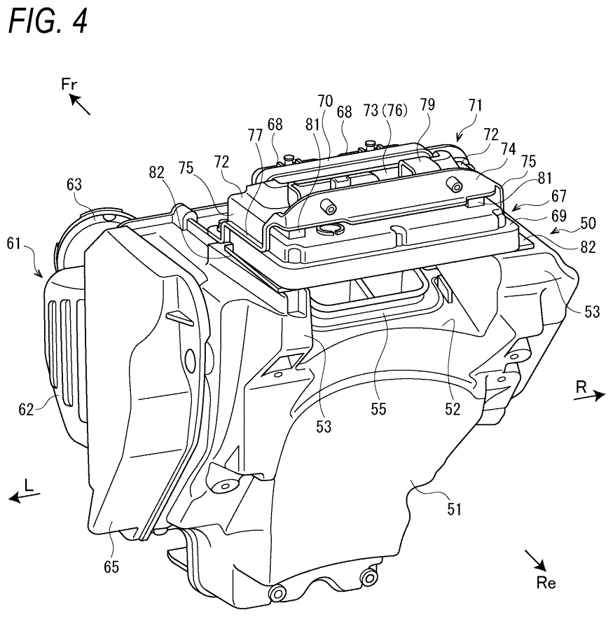

The air cleaner of the present embodiment will be described with reference to FIGS. 2 to 4. FIG. 2 is a top view of a periphery of an air cleaner according to the present embodiment. FIG. 3 is a perspective view of the periphery of the air cleaner according to the present embodiment. FIG. 4 is a perspective view of the air cleaner according to the present embodiment. FIGS. 2 and 3 illustrate a state in which the seat is removed from the vehicle body frame.

As illustrated in FIGS. 2 and 3, a pair of upper seat rails 16 extend rearward from upper parts of the pair of body frames 13, and a pair of lower seat rails 17 extend diagonally upward and rearward from lower parts of the pair of body frames 13. Rear ends of the pair of lower seat rails 17 are connected to rear ends of the pair of upper seat rails 16. In addition, the rear ends of the pair of upper seat rails 16 are connected via a seat bridge 18. In a side view, the air cleaner 50 is disposed in a space that is triangular in side view and is surrounded by the body frame 13, the upper seat rail 16, and the lower seat rail 17.

An ECM 67 is disposed on an upper surface of a cleaner case 51 of the air cleaner 50 as an electrical component. A front side of the ECM 67 bulges upward, and a pair of connectors 68 are provided on this bulging portion 70. A periphery of the bulging portion 70 is pressed down from above by a lid (cover member) 71 that is U-shaped when viewed from above. Front sides of the lid 71 that is bifurcated is fixed to the upper surface of the air cleaner 50 by a pair of bolts 83, and a rear side of the lid 71 is fixed to the seat bridge 18 by a pair of clips 84. A rear side of the lid 71 is lowered by one step between the bulging portion 70 and the seat bridge 18, and a holding claw 78 and a holder 79 for holding a tool 85 are formed in a recess of the lid 71.

An inlet tube 55 (see FIG. 4) is provided on an upper rear surface of the cleaner case 51, and an outlet tube 61 is provided on a front side of the cleaner case 51. A filter (not illustrated) is installed inside the cleaner case 51, and air taken in through the inlet tube 55 is filtered by the filter and sent to the outlet tube 61. The outlet tube 61 is connected to the engine 41 via an electronically controlled throttle 87 and an intake pipe 88. Air is sent from the outlet tube 61 to the electronically controlled throttle 87, and after an intake amount is adjusted by the electronically controlled throttle 87, the air is supplied to the engine 41 through the intake pipe 88.

As illustrated in FIGS. 3 and 4, the air cleaner 50 is configured by interposing a separate plate 64 between the cleaner case 51 on a dirty side and the outlet tube 61 on a clean side. The cleaner case 51 is formed in a box shape having an open front and a triangular shape in a side view, and a filter is installed inside the cleaner case 51. An access window (not illustrated) is formed on a left side surface of the cleaner case 51, and a side cap 65 is removably attached to the access window. By removing the side cap 65 from the cleaner case 51, the filter inside the cleaner case 51 can be replaced periodically.

An upstream side of the outlet tube 61 forms a chamber portion 62 that is connected to the cleaner case 51, and a downstream side of the outlet tube 61 forms a passage portion 63 that leads to the engine 41 (see FIG. 2). The chamber portion 62 curves leftward toward the front so as to avoid the rear suspension 33 (see FIG. 1), and the passage portion 63 having a cylindrical shape protrudes forward from a front end of the chamber portion 62. The separate plate 64 forms a front wall of the cleaner case 51, and an opening (not illustrated) is formed in a center of the separate plate 64, connecting an intake chamber in the cleaner case 51 and an intake passage in the outlet tube 61.

As described above, the ECM 67 is supported from below by the cleaner case 51. In this case, the upper surface of the cleaner case 51 is recessed to form a recess 52 and a pair of bulging walls 53. The pair of bulging walls 53 face each other across the recess 52, and the ECM 67 is supported at both ends by the pair of bulging walls 53. The front and both sides of the recess 52 are closed by wall surfaces, while the top and rear of the recess 52 are open. The inlet tube 55 is inserted into a bottom surface of the recess 52, with an intake port of the inlet tube 55 facing upward. The intake port of the inlet tube 55 is covered from above by the ECM 67 to prevent foreign matter from entering the intake port.

The ECM 67 has a plate-shaped case 69 having a thin, rectangular shape, the bulging portion 70 that bulges out from a front upper surface of the plate-shaped case 69, and the pair of connectors 68 provided on a front surface of the bulging portion 70. A circuit board is accommodated inside the plate-shaped case 69, and various electronic components such as a processor and a memory are mounted on the circuit board. The plate-shaped case 69 has two stages, an upper stage portion and a lower stage portion, and the lower stage portion of the plate-shaped case 69 is formed wider in a vehicle width direction than the upper stage portion. The bulging portion 70 bulges upward from a front side of the plate-shaped case 69, and mounting openings of the pair of connectors 68 face forward. A harness (not illustrated) extending from an external device is connected to the pair of connectors 68 from the front side.

The top of the ECM 67 is covered by the lid 71 with a gap between the ECM 67 and the lid 71. The lid 71 is formed into a U-shape when viewed from above by a pair of vertical frame portions 72 on both sides of the bulging portion 70 and a horizontal frame portion 73 at the rear of the bulging portion 70. Tip portions of the pair of vertical frame portions 72 are fixed to a pair of bosses 54 of the cleaner case 51 with the bolts 83, and a rear plate 74 rising from a rear edge of the horizontal frame portion 73 is fixed to a front surface of the seat bridge 18 with the clips 84. A pair of side plates 75 extending down from outer edges of the pair of vertical frame portions 72 are in contact with both side surfaces of the upper stage portion of the plate-shaped case 69, and an inclined portion 76 on a front edge of the horizontal frame portion 73 covers a raised portion of the bulging portion 70.

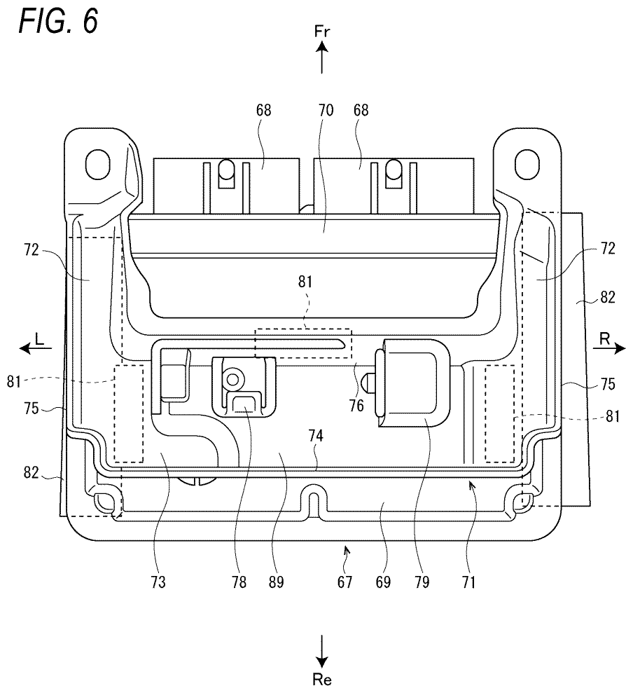

Three upper cushions (first cushions) 81 are sandwiched between the lid 71 and the ECM 67. The two upper cushions 81 extend in a front-rear direction, and these upper cushions 81 are interposed between the pair of vertical frame portions 72 and the ECM 67. One upper cushion 81 extends in the vehicle width direction, and this upper cushion 81 is interposed between the inclined portion 76 at the front edge of the horizontal frame portion 73 and the ECM 67 (see FIG. 6). The holder 79 for the tool 85 and the like are provided in the recess of the lid 71, and the upper cushions 81 are installed at three locations avoiding the recess of the lid 71. The upper cushion 81 is formed of a foam rubber cushion having a thickness of 10 mm, such as Eptsealer (registered trademark).

A pair of lower cushions (second cushions) 82 are sandwiched between the air cleaner 50 and the ECM 67. The pair of lower cushions 82 extend in the front-rear direction, and these lower cushions 82 are interposed between the pair of bulging walls 53 and the ECM 67. The lower cushion 82 is formed of, for example, expanded polyolefin foam such as PE-Lite (registered trademark) having a thickness of 3 mm, or polyethylene foam such as EVA foam having a thickness of 3 mm. In this manner, the ECM 67 is fixed in a floating manner between the lid 71 and the air cleaner 50 by the upper cushion 81 and the lower cushion 82.

The upper cushion 81 and the lower cushion 82 absorb small engine vibration, thereby suppressing the effect of the engine vibration on the ECM 67. Further, restricting portions 77 are formed on lower sides of a pair of side plates 75 of the lid 71, and the lower stage portion of the ECM 67 protrudes like a flange below the pair of restricting portions 77. The pair of restricting portions 77 face the lower stage portion of the ECM 67 with a gap therebetween in an up-down direction. When vibration larger than engine vibration occurs due to jump driving or the like, the pair of restricting portions 77 abut against the lower stage portion of the ECM 67, restricting the displacement of the ECM 67 and suppressing the effect of the large vibration on the ECM 67.

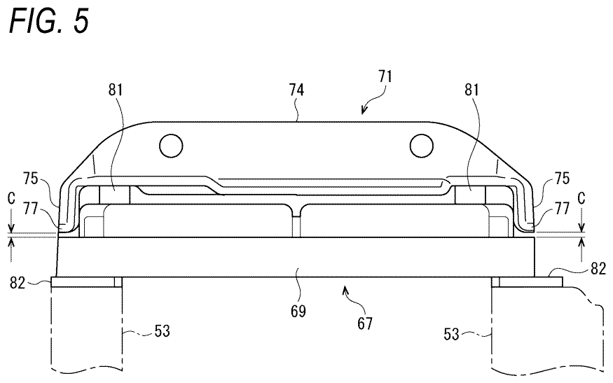

A detailed configuration of the ECM installation structure will be described with reference to FIGS. 5 and 6. FIG. 5 is a rear view of a periphery of the ECM according to the present embodiment. FIG. 6 is a top view of the periphery of the ECM according to the present embodiment.

As illustrated in FIG. 5, the ECM 67 is supported from below by the pair of bulging walls 53 of the cleaner case 51 via the pair of lower cushions 82. The lower cushion 82 is formed to be relatively thin, and the ECM 67 is positioned slightly higher than upper surfaces of the pair of bulging walls 53. The ECM 67 is pressed down from above by the lid 71 with three upper cushions 81 interposed therebetween. The upper cushion 81 is formed to be relatively thick, and a sufficient gap is provided between the lid 71 and the ECM 67. The pair of side plates 75 of the lid 71 extend along side surfaces of the upper stage portion of the ECM 67, and the restricting portions 77 on the lower sides of the pair of side plates 75 face the lower stage portion of the ECM 67 with a gap C therebetween.

A gap is provided between the pair of restricting portions 77 and the ECM 67 that is larger than the amount of displacement of the ECM 67 caused by engine vibration and smaller than the amount of displacement of the ECM 67 caused by vibration larger than the engine vibration. For example, when engine vibration is 50 Hz or more, the amount of displacement of the ECM 67 is 0.4 mm, and when vibration larger than the engine vibration is less than 50 Hz, the amount of displacement of the ECM 67 is 4.75 mm. Therefore, for example, a gap larger than 0.4 mm and smaller than 4.75 mm is provided between the pair of restricting portions 77 and the ECM 67.

During normal driving, engine vibration is transmitted from the pair of bulging walls 53 of the cleaner case 51 through the lower cushions 82 to the ECM 67, and also from the cleaner case 51 through the lid 71 and the upper cushion 81 to the ECM 67. Since the pair of restricting portions 77 do not come into contact with the ECM 67 due to engine vibration, the engine vibration is not directly transmitted from the lid 71 to the ECM 67. Since engine vibration is transmitted from the air cleaner 50 and the lid 71 to the ECM 67 via the lower cushion 82 and the upper cushion 81, a high vibration isolation effect can be obtained by the lower cushion 82 and the upper cushion 81.

During jump driving, vibration larger than engine vibration is generated. Vibration is transmitted from the cleaner case 51 (see FIG. 4) to the ECM 67 via the pair of bulging walls 53 and the lid 71. In this case, the pair of restricting portions 77 of the lid 71 come into contact with the lower stage portion of the ECM 67, thereby restricting the displacement of the ECM 67 and reducing an impact applied to the ECM 67. In particular, when the gap between the pair of restricting portions 77 and the ECM 67 is made slightly larger than the amount of displacement of the ECM 67 due to engine vibration, the impact applied to the ECM 67 can be effectively mitigated. Additionally, the deformation of the lower cushion 82 and the upper cushion 81 also serves to reduce the impact applied to the ECM 67.

The upper surface of the ECM 67 is formed in a stepped (convex) shape so as to fit into the pair of side plates 75 of the lid 71. Opposing surfaces of the pair of side plates 75 are in contact with both side surfaces of the upper stage portion of the ECM 67, thereby suppressing rattling of the ECM 67 in the vehicle width direction when vibration larger than engine vibration occurs. Furthermore, even when the ECM 67 is fixed to the air cleaner 50 in a floating manner, the ECM 67 is positioned relative to the air cleaner 50. The rattle of the ECM 67 from front to rear is suppressed by the contact between the upper cushion 81 on the back side of the inclined portion 76 of the lid 71 and the bulging portion 70 and by the connection between the pair of connectors 68 and the harness.

A vertical gap between the lid 71 and the ECM 67 is greater than a vertical gap between the cleaner case 51 and the ECM 67. Since a space of sufficient height is secured above the ECM 67, the amount of compression of the upper cushion 81 can be adjusted by selecting the material of the upper cushion 81 according to the vehicle vibration, and vibration and impact can be suppressed. By narrowing the space below the ECM 67, the ECM 67 is brought closer to the air cleaner 50. Furthermore, the lower cushion 82 is formed to be harder than the upper cushion 81. With these configurations, the ECM 67 is stably installed on the lower cushion 82.

Both side portions of the ECM 67 are supported by the pair of bulging walls 53 of the cleaner case 51, but a central portion of the ECM 67 is positioned in the recess 52 of the pair of bulging walls 53 and is not in contact with the cleaner case 51. A contact area between the ECM 67 and the pair of bulging walls 53 is reduced, thereby suppressing engine vibration transmitted from the air cleaner 50 to the ECM 67. Furthermore, an area over which the lower cushion 82 is attached to the cleaner case 51 is reduced, resulting in reduced costs. The ECM 67 is installed on the upper surfaces of the pair of bulging walls 53, and the ECM 67 also functions as a hood for a suction port of the inlet tube 55 (see FIG. 4).

The pair of upper cushions 81 are disposed at a distance from each other in a longitudinal direction of the ECM 67, and the lid 71 is recessed between the pair of upper cushions 81. The holder 79 and the holding claw 78 are provided in a concave 89 of the lid 71, and the tool 85 (see FIG. 2) can be placed on the holder 79 and the holding claw 78. An end of the tool 85 fits inside the holder 79, and a middle portion of the tool 85 is hooked onto the holding claw 78. The rigidity of the lid 71 can be increased without increasing a thickness of the lid 71 by providing the concave 89 in the lid 71 or providing the tool 85 thereon. In addition, the space between the pair of upper cushions 81 can be utilized to place the tool 85 therein.

As described above, according to the air cleaner 50 of the present embodiment, the ECM 67 is fixed in a floating manner between the lid 71 and the air cleaner 50 via the upper cushion 81 and the lower cushion 82. The engine vibration is absorbed by the upper cushion 81 and the lower cushion 82, thereby suppressing the effect of the engine vibration on the ECM 67. When vibration larger than engine vibration occurs, the displacement of the ECM 67 is restricted by the restricting portion 77 of the lid 71, and the acceleration of the ECM 67 is reduced by the deformation of the upper cushion 81 and the lower cushion 82, thereby mitigating the impact applied to the ECM 67. In this manner, the effects of engine vibration and vibration larger than engine vibration on the ECM 67 are reduced.

In the present embodiment, the ECM is described as an embodiment of the electrical component, but the electrical component may be a component other than the ECM, such as a Capacitive Discharge Ignition (CDI).

In addition, in the present embodiment, a lid that is U-shaped when viewed from above is provided as the cover member, but the shape of the cover member is not particularly limited as long as the cover member is formed to cover the upper part of the electrical component with a gap.

Furthermore, in the present embodiment, three upper cushions are sandwiched between the lid and the ECM, but the number and shape of the upper cushions are not particularly limited.

In addition, in the present embodiment, the pair of lower cushions are sandwiched between the air cleaner and the ECM, but the number and shape of the lower cushions are not particularly limited.

In addition, in the present embodiment, the upper cushion is formed to be thicker than the lower cushion, but the lower cushion may be formed to be thicker than the upper cushion, or the lower cushion and the upper cushion may be formed to have the same thickness.

In addition, in the present embodiment, the lower cushion is formed to be harder than the upper cushion, but the upper cushion may be formed to be harder than the lower cushion, or the lower cushion and the upper cushion may be formed to have the same hardness.

Furthermore, the electrical component installation structure of the present embodiment is not limited to being adopted in the above-described saddle-type vehicle, but may be adopted in other types of saddle-type vehicles. A saddle-type vehicle is not limited to all vehicles in which a rider sits astride a seat, but also includes scooter-type vehicles in which a rider does not sit astride a seat.

As described above, a first aspect is an electrical component installation structure including an air cleaner (50) connected to an engine (41) of a saddle-type vehicle (1), an electrical component (ECM 67) supported from below by the air cleaner, a cover member (lid 71) that covers an upper part of the electrical component with a gap, a first cushion (upper cushion 81) sandwiched between the cover member and the electrical component, and a second cushion (lower cushion 82) sandwiched between the air cleaner and the electrical component, where the cover member is formed with a restricting portion (77) for restricting displacement of the electrical component when vibration larger than engine vibration occurs. According to this configuration, the electrical component is fixed in a floating manner between the cover member and the air cleaner via the first and second cushions. Engine vibration is absorbed by the first and second cushions, reducing the effect of engine vibration on the electrical component. When vibration larger than engine vibration occurs, the displacement of the electrical component is restricted by the restricting portion of the cover member, and the acceleration of the electrical component is reduced by the deformation of the first and second cushions, thereby mitigating the impact applied to the electrical component. In this way, the effects of engine vibration and vibration larger than engine vibration on the electrical component are reduced.

In a second aspect, in the first aspect, a gap larger than the amount of displacement of the electrical component due to engine vibration is provided between the restricting portion of the cover member and the electrical component. According to this configuration, engine vibration is not directly transmitted from the cover member to the electrical component, and a high vibration isolation effect can be obtained by the first and second cushions. Furthermore, when the gap between the restricting portion and the electrical component is made slightly larger than the amount of displacement of the electrical component due to engine vibration, the impact applied to the electrical component can be effectively mitigated.

In a third aspect, in the first or second aspect, the engine vibration is equal to or greater than 50 Hz, and the vibration larger than the engine vibration is less than 50 Hz. According to this configuration, the influence of relatively small vibration of 50 Hz or more and relatively large vibration of less than 50 Hz on the electrical component can be suppressed.

In a fourth aspect, in any one of the first to third aspects, a pair of side plates (75) extend downward from both side edges of the cover member in a vehicle width direction, an upper surface of the electrical component is formed in a convex shape so as to fit into the pair of side plates, and the restricting portions are formed at lower ends of the pair of side plates, and opposing surfaces of the pair of side plates are in contact with the electrical component. According to this configuration, the influence of engine vibration is suppressed, while rattling of the electrical component in the vehicle width direction when vibration larger than the engine vibration occurs is also suppressed. Furthermore, even when the electrical component is fixed to the air cleaner in a floating manner, the electrical component is positioned relative to the air cleaner.

In a fifth aspect, in any one of the first to fourth aspects, a gap between the cover member and the electrical component is greater than a gap between the air cleaner and the electrical component. According to this configuration, a space of sufficient height is secured above the electrical component, and by selecting the material of the first cushion according to the vehicle vibration, the amount of compression of the first cushion can be adjusted, thereby suppressing vibration and impact. By narrowing the space below the electrical component, the electrical component can be brought closer to the air cleaner, and the electrical component can be installed more stably.

In a sixth aspect, in any one of the first to fifth aspects, the second cushion is harder than the first cushion. According to this configuration, the electrical component can be stably placed on the second cushion.

In a seventh aspect, in any one of the first to sixth aspects, the first cushion is a pair of first cushions spaced apart from each other in a longitudinal direction of the electrical component, and the cover member has a recess between the pair of first cushions, the recess being formed so that a tool (85) can be placed in the recess. According to this configuration, the rigidity can be increased without increasing the thickness of the cover member. A space between the pair of first cushions can be utilized to place the tool.

In an eighth aspect, in any one of the first to seventh aspects, an upper surface of the air cleaner is recessed to form a recess (52) and a pair of bulging walls (53) sandwiching the recess, and the electrical component is supported by the pair of bulging walls via the second cushion. According to this configuration, a contact area between the electrical component and the air cleaner is reduced, thereby suppressing engine vibration transmitted from the air cleaner to the electrical component. Moreover, an area over which the second cushion is attached to the air cleaner can be reduced.

Although the present embodiment is described, other embodiments may be made by combining the above-described embodiment and modification embodiments in whole or in part.

Furthermore, the technology of the present invention is not limited to the above-described embodiment, and may be modified, substituted, or changed in various ways without departing from the spirit and scope of the technical concept. Furthermore, when technological advances or derived technologies allow the technical ideas to be realized in a different way, they may be implemented using that method. Therefore, the claims cover all embodiments that may fall within the scope of the technical concept.

What is claimed is:

1. An electrical component installation structure, comprising:
an air cleaner connected to an engine of a saddle-type vehicle;
an electrical component supported from below by the air cleaner;
a cover member covering an upper part of the electrical component with a gap;
a first cushion sandwiched between the cover member and the electrical component; and
a second cushion sandwiched between the air cleaner and the electrical component, wherein
the cover member includes a restricting portion configured to restrict a displacement of the electrical component when a vibration larger than an engine vibration occurs.

2. The electrical component installation structure according to claim 1, wherein
a gap larger than an amount of a displacement of the electrical component due to the engine vibration is provided between the restricting portion of the cover member and the electrical component.

3. The electrical component installation structure according to claim 1, wherein
the engine vibration is equal to or greater than 50 Hz, and
the vibration larger than the engine vibration is less than 50 Hz.

4. The electrical component installation structure according to claim 1, wherein
a pair of side plates extend downward from both side edges of the cover member in a vehicle width direction of the saddle-type vehicle,
an upper surface of the electrical component has a convex shape so as to enter into the pair of side plates,
the restricting portion is formed at each of lower ends of the pair of side plates, and
opposing surfaces of the pair of side plates are in contact with the electrical component.

5. The electrical component installation structure according to claim 1, wherein
a gap between the cover member and the electrical component is greater than a gap between the air cleaner and the electrical component.

6. The electrical component installation structure according to claim 1, wherein
the second cushion is harder than the first cushion.

7. The electrical component installation structure according to claim 1, wherein
the first cushion is a pair of cushions spaced apart from each other in a longitudinal direction of the electrical component, and
the cover member has a recess between the pair of cushions of the first cushion, so that a tool can be placed in the recess.

8. The electrical component installation structure according to claim 1, wherein
an upper surface of the air cleaner is recessed to form a concave and a pair of bulging walls sandwiching the concave, and
the electrical component is supported by the pair of bulging walls via the second cushion.

9. The electrical component installation structure according to claim 1, wherein
a thickness of the first cushion is larger than a thickness of the second cushion.
